(19) United States
(12) Patent Application Publication
(10) Pub. No.: US 2023/0215703 A1
(43) Pub. Date: Jul. 6, 2023

(54) SEALING SURFACES OF COMPONENTS USED IN PLASMA ETCHING TOOLS USING ATOMIC LAYER DEPOSITION

(71) Applicant: Lam Research Corporation, Fremont, CA (US)

(72) Inventors: Robin KOSHY, Fremont, CA (US); Lin XU, Fremont, CA (US); John DAUGHERTY, Fremont, CA (US)

(21) Appl. No.: 18/009,238

(22) PCT Filed: Jun. 15, 2021
(86) PCT No.: PCT/US2021/037451

§ 371 Date: Dec. 8, 2022

Related U.S. Application Data
(60) Provisional application No. 63/042,913, filed on Jun. 23, 2020.

(51) Int. Cl. H01J 37/32; C23C 16/04; C23C 16/24

(52) U.S. Cl. CPC H01J 37/32495; C23C 16/24; C23C 16/045; H01J 37/3244; H01J 37/32513; H01J 37/32853; H01J 2237/334; H01J 2237/3321

(57) ABSTRACT

Sealing various machined component parts used in plasma etching chambers using an Atomic Layer Deposition (ALD) coating. By sealing the component parts with the ALD layer, surface erosion/etch caused by repeated exposure to plasma during workpiece fabrication is eliminated or significantly mitigated. As a result, unwanted particle generation, caused by erosion, is eliminated or significantly reduced, preventing contamination within the plasma etching chamber.

### CROSS-REFERENCE TO RELATED APPLICATION

This application claims the benefit of priority of U.S. Application No. 63/042,913, filed Jun. 23, 2020, which is incorporated herein by reference for all purposes.

### FIELD OF THE DISCLOSURE

The present disclosure pertains to fabricating component parts used in plasma etching tools, and more particularly, to sealing machined component parts using an Atomic Layer Deposition (ALD) coating, preventing or at least mitigating surface erosion caused by repeated exposure to plasma during workpiece fabrication.

### BACKGROUND

The background description provided here is for the purpose of generally presenting the context of the present disclosure. Anything described in this background section, and potentially aspects of the written description, are not expressly or impliedly admitted as prior art with respect to the present application.

Plasma etching tools are well known for etching various types of workpieces, such as semiconductor wafers and flat panel displays. With plasma etching tools, reactive gases, such as oxygen or fluorine, are introduced into a processing chamber containing a workpiece. When Radio Frequency (RF) energy is applied, plasma is generated. Ions or other reactants in the plasma bombard the surface of the workpiece, removing or etching away material. The resulting volatile material is then removed from the chamber by a vacuum system.

One problem with plasma etching tools is that surfaces of component parts within the chamber are repeatedly exposed to plasma during the etching of workpieces. As a result, these surfaces tend to erode, generating particles that contaminate the processing chamber and potentially deposit on the workpiece, often causing processing defects and reducing yields.

A way to reduce surface erosion of component parts within plasma etching chambers, eliminating or at least mitigating the generation of contaminating particles, is therefore needed.

### SUMMARY

The present application is directed an Atomic Layer Deposition (ALD) coating that is deposited onto surfaces of component parts used in a plasma etching chamber. The ALD coating acts to seal surface defects that are susceptible to particle generation, such as cracks or loose or semi-loose debris resulting from machine fabrication and/or repeated use of the component parts. By sealing the surface defects, the generation of unwanted particles and other contaminants within the plasma etching chamber is eliminated or mitigated. The ALD coating thus in effect acts as a “glue” layer, holding together surfaces that are otherwise prone to breakdown and particle generation.

In non-exclusive embodiments, the present application is directed to a gas dispensing component for use in a plasma etching chamber. The gas dispensing component includes one or more gas conduits machined into the gas dispensing component and an Atomic Layer Deposition (ALD) coating formed on at least portions of the internal walls of the one or more gas conduits. The ALD coating acts to seal surface defects, such as cracks or loose or semi-loose debris resulting from machining and/or repeated use. With the ALD coating, the surface defects are in effect sealed by a “glue” layer, eliminating or mitigating the generation of unwanted particles and other contaminants within the plasma etching chamber caused by surface erosion.

In various alternative embodiments, the gas dispensing component is fabricated from one of the following, including silicon, ceramics including aluminum oxide (Al₂O₃, also sometimes referred to as alumina) or yttrium oxide (Y₂O₃), non-oxide ceramic, other materials including yttrium, silicon carbide, or aluminum or any other suitable material. The ALD coating is selected from the group including aluminum oxide, yttrium, yttrium aluminum oxide, yttrium oxide, silicon or other silicon-based coatings including silicon oxide (SiO₂) or any other material suitable for use within a plasma etching chamber.

In one specific but by no means exclusive embodiment, the gas dispensing component is fabricated from silicon and the ALD coating is also silicon.

In yet other embodiment, the deposited ALD coating deposited on the internal walls of the one or more gas conduits is non-uniform in thickness, ranging in thickness from 20 to 500 nanometers, and is generally thicker at gas outlets(s) of the one or more gas conduits and gradually tapers along the length of the conduits respectively. In other embodiments, the ALD layer is of substantially uniform thickness.

In other embodiments, the one or more gas conduits are machined by drilling into the gas dispensing component using Electrical Discharge Machining (EDM). In alternative embodiments, the one or more gas conduits may have a diameter of approximately 500 microns, in a range of 400 to 600 microns, less than 600 microns, more than 400 microns. The one or more gas conduits may have an aspect ratio of approximately 30:1, in a range of 20:1 to 40:1, more than 20:1, less than 40:1.

In yet other non-exclusive embodiments, the gas dispensing component is a showerhead for use in a Capacitively Coupled Plasma (CCP) or a gas dispensing nozzle for use in an Inductively Coupled Plasma (ICP) type plasma chamber.

Another non-exclusive embodiment is directed to a component made of silicon for use in a plasma etching chamber. The component includes an Atomic Layer Deposition (ALD) coating deposited on at least a portion of the component, the ALD coating eliminating or mitigating erosion of at least the portion of the component covered by the ALD coating when exposed to an environment within the plasma etching chamber. In various embodiments, the ALD coating ranges in thickness from 20 to 500 nanometers. In one non-exclusive embodiment, the component is a machined silicon ring that is intended to surround an edge periphery of a semiconductor wafer to tailor the feature profile on the wafer edge. In other non-exclusive embodiments, the component is a showerhead-electrode or gas dispensing nozzle for supplying gas into a CCP or ICP type etching chamber respectively. In yet other embodiments, the component may be any component that is used within a plasma processing chamber.

Another non-exclusive embodiment is directed toward a method to fabricate a component for use in a plasma etching chamber. The method involves fabricating the component from a material, machine drilling one or more holes into the material of the component, wet etching internal surfaces of the one or more holes drilled into the material of the component and depositing an ALD coating using an Atomic Layer Deposition process at least partially onto internal surfaces of the one or more holes drilled into the material of the component, the ALD coating acting to seal surface defects on the internal surfaces resulting from the drilling of the one or more holes. In various alternatives, the ALD coating deposited using the ALD process has a thickness in the range of 20 to 500 nanometers. In one embodiment, the component is a showerhead-electrode for use in a CCP etching chamber and the machined holes are provided for supplying gas into the CCP chamber. In another embodiment, the component is a gas nozzle for supplying gas into an Inductively Coupled Plasma (ICP) etching chamber. In either case, the ALD coating prevents or mitigates particle generation caused by erosion when the component is exposed to plasma. In various other embodiments, the material the component is fabricated from silicon, ceramics including aluminum oxide (Al₂O₃) or yttrium oxide (Y₂O₃), non-oxide ceramic, silicon carbide or aluminum. The ALD coating is selected from the group including aluminum oxide, yttrium, yttrium aluminum oxide, yttrium oxide, silicon, or other silicon-based coatings including silicon oxide (SiO₂).

### BRIEF DESCRIPTION OF THE DRAWINGS

The present application, and the advantages thereof, may best be understood by reference to the following description taken in conjunction with the accompanying drawings in which:

FIG. 1 is a block diagram of a Capacitively Coupled Plasma (CCP) etching tool in accordance with a non-exclusive embodiment.

FIG. 2 illustrates a gas-dispensing surface of a showerhead-electrode used in a CCP etching tool in accordance with a non-exclusive embodiment.

FIG. 3 shows a cross-section of several representative gas-dispensing conduits of the showerhead-electrode in accordance with a non-exclusive embodiment.

FIG. 4 is a cross-section block diagram of an Inductively Coupled Plasma (ICP) etching tool in accordance with a non-exclusive embodiment.

FIG. 5 shows a cross-section of a nozzle used in an ICP etching tool in accordance with another non-exclusive embodiment.

FIG. 6 shows a cross-section of a pedestal for supporting a workpiece within a processing chamber of either a CCP or ICP etching tool in accordance with an embodiment.

FIGS. 7A and 7B illustrate a coupling ring with an ALD coating for use either a CCP or ICP etching tool in accordance with an embodiment.

FIG. 8 is a flow diagram illustrating fabrication steps for fabricating a component part for use in either a CCP or ICP etching tool in accordance with an embodiment.

FIG. 9 is a flow diagram of an ALD process used to coat component parts used in either a CCP or ICP etching tool in accordance with an embodiment.

FIG. 10 is a schematic cross-sectional view of another semiconductor processing system that uses another embodiment.

In the drawings, like reference numerals are sometimes used to designate like structural elements. It should also be appreciated that the depictions in the figures are diagrammatic and not necessarily to scale.

### DETAILED DESCRIPTION

The present application will now be described in detail with reference to a few non-exclusive embodiments thereof as illustrated in the accompanying drawings. In the following description, numerous specific details are disclosed for the purpose of providing a thorough understanding of the present disclosure. It will be apparent, however, to one skilled in the art, that the present discloser may be practiced without some or all of these specific details. In other instances, well-known process steps and/or structures have not been described in detail so the present disclosure is not unnecessarily obscured.

### Capacitively Coupled Plasma Tools

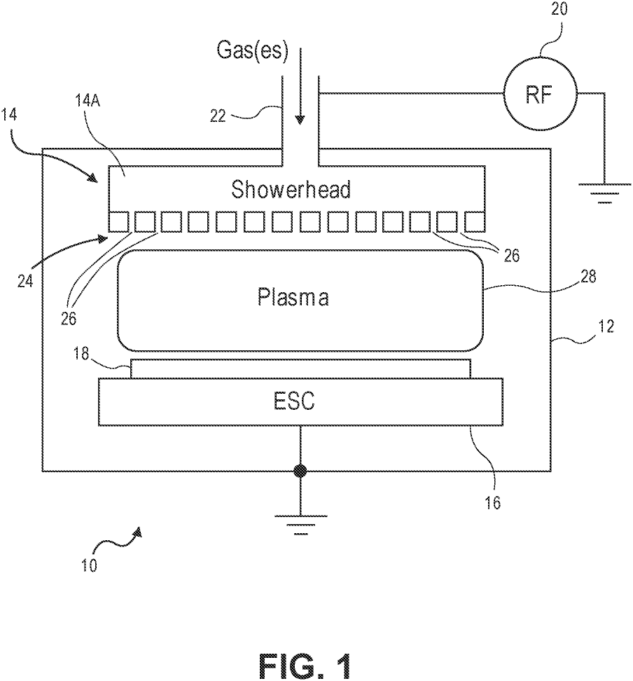

Referring to FIG. 1, a block diagram of a Capacitively Coupled Plasma (CCP) etching tool 10 is illustrated. The CCP tool 10 includes a chamber 12, a showerhead-electrode 14 for dispensing gas into the chamber 12, an Electrostatic Chuck (ESC) 16 for clamping a workpiece 18, and a Radio Frequency (RF) power supply 20 that is coupled to the showerhead-electrode 14.

The showerhead-electrode 14 includes a component body 14A, a gas supply plenum 22 and a gas dispensing surface 24 that opposes the workpiece 18 within the chamber 12. The gas dispensing surface 24 includes a plurality of gas conduits 26 that are machined into the component body 14A of the showerhead-electrode 14, defining gas outlets on the gas dispensing surface 24. In a non-exclusive embodiment, the component body 14A showerhead-electrode 14 is fabricated from silicon; the holes defined by the gas conduits 26 have a diameter of approximately 500 microns and are machined into the showerhead-electrode 14 using Electrical Discharging Machining, often referred to as “EDM”. Although EDM is a precise method of machining, surface defects such as cracks, waffling, undercutting, or overhanging may still occur within the internal sidewalls of the gas conduits 26. To help ameliorate these surface defects, a wet or chemical etch may optionally be performed, helping reduce the extent of the cracking, waffling, undercutting and/or overhanging of material on the internal sidewalls of the gas conduits 26.

It should be understood that the component body 14A of the showerhead-electrode 14 may be fabricated from a wide variety of different materials and is not limited to silicon. For example, the showerhead-electrode 14 may be fabricated from (a) silicon, (b) non-oxide ceramic, (c) oxide, (d) ceramic, (e) silicon carbide, (f) aluminum oxide, (g) aluminum or just about any other material suitable for operation within a plasma environment Furthermore, the diameter of the holes defined by the gas conduits 26 may widely vary. The diameter may range from 400 to 600 microns, or be less than 400 microns or more than 600 microns. As a general rule, the diameter may vary based on factors, such as desired gas flow rates, types of gases, and other factors. The gas conduits 26 may also be machined in different ways other than EDM, such as the use of additive manufacturing (sometime referred to as “3D printing”), mechanical drilling, milling, computer numerical control (CNC) machining, etc.

During operation, one or more gases are supplied via the gas supply plenum 22 to the showerhead-electrode 14. Within the component body 14A of the showerhead-electrode 14, the one or more gases is/are distributed via an internal gas supply network (not illustrated) and dispensed through the plurality of gas conduits 26 above the workpiece 18. When energy from the RF supply 20 is applied to the showerhead-electrode 14, plasma 28 is generated in the chamber 12. The plasma 28 is said to be a “Capacitively Coupled Plasma” (CCP) because it spaced between two electrodes, namely the showerhead-electrode 14 and the ESC 16 coupled to ground. With the plasma 28 present in the chamber 12, ions or other radicals bombard the surface of the workpiece 18, removing or etching away exposed layers of material. The resulting volatile material is then removed from the chamber 12 by a vacuum system (not illustrated).

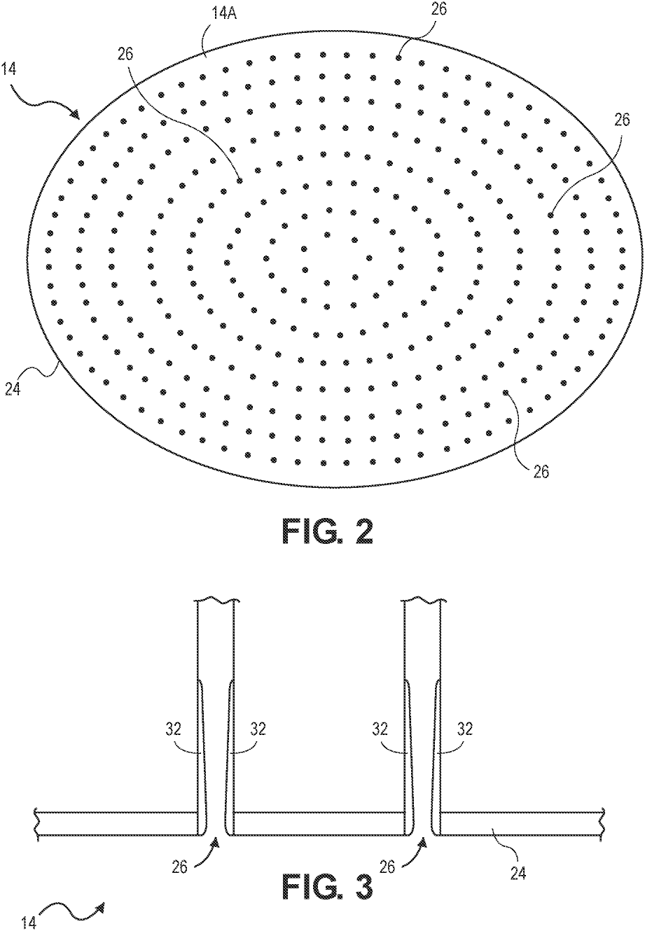

Referring to FIG. 2, the gas dispensing surface 24 of the component body 14A of the showerhead-electrode 14 is illustrated. In this particular embodiment, the holes defined by the gas conduits 26 on the gas dispensing surface 24 of the component body 14 are arranged in concentric circles. In this manner, the gas or gases supplied into the chamber 12 are widely and evenly dispersed above the workpiece 18. It should be understood that the particular pattern shown is merely exemplary and should not be construed as limiting in any regard. On the contrary, the gas conduits 26 may be arranged in any pattern, such as in rows and columns, various spirals, other geometric or non-geometric patterns, etc.

The gas conduits 26 typically have a large aspect ratio, meaning their length is significantly larger than their diameter. In various embodiments, the gas conduits 26 may have aspect ratios that are approximately 30:1, in a range of 20:1 to 40:1, more than 20:1 or less than 40:1. Again, the specific aspect ratios listed herein are merely exemplary and the gas conduits 26 may have any aspect ratio.

The Applicant has found that the internal walls of the gas conduits 26 are particularly prone to erosion and unwanted particle generation caused by the repeated and/or prolonged exposure to the plasma 28 during the processing of workpieces 18. As previously noted, the machining of the gas conduits 26 typically results in surface defects including cracks, waffling, undercutting and/or overhanging of material. As these surfaces are repeatedly exposed to the plasma 28, the defects are susceptible to material breakdown, resulting in particles flaking off and contaminating the chamber 12. To eliminate or at least mitigate this problem, the Applicant proposes sealing at least portions of the showerhead-electrode 14, including at least portions of the internal walls of the gas conduits 26, using an Atomic Layer Deposited (“ALD”) coating. For instance, by ALD coating at least partially the machined surfaces of the internal walls of the gas conduits 26, the surface cracks, waffling, and undercuts and overcuts are effectively sealed. As a result, the internal walls or surfaces of the gas conduits 26 are significantly less prone to material breakdown due to exposure to the plasma 28. Particle generation and contaminants are therefore eliminated or at least mitigated, significantly improving workpiece yields.

Referring to FIG. 3, a cross-section of several representative gas conduits 26 with an ALD coating 32 is illustrated. To form the ALD coating 32, the component body 14A of the showerhead-electrode 14 is placed into an ALD processing tool and is subject to multiple ALD cycles. During the ALD cycles, precursors migrate up into the individual gas conduits 26 and particles deposit on the sidewalls, forming the ALD coating 32. The number of ALD cycles is generally dependent on the desired thickness of the ALD coating 32.

During ALD cycles, the degree of precursor migration along the length of the gas conduits 26 tends to be less compared to in the vicinity of the gas outlets of the gas conduits 26. As a result, the ALD coating 32 tends to deposit thicker near the gas outlets of the gas conduits 26 but tapers in thickness along the length of the gas conduits 26. The resulting ALD coating 32 may, therefore, be non-uniform. Since the gas outlets of the gas conduits 26 bear the most exposure to the plasma 28, these areas tend to be the most susceptible to erosion. Having the ALD coating 32 thicker in these regions is therefore beneficial. In other embodiments, the ALD coating may be deposited during the ALD process so that it is uniform. This is generally accomplished by extending the individual half-cycles of each ALD cycle a bit longer to allow more precursors to migrate along the length of the conduits. As a result, the ALD coating 32 will be more uniform in thickness.

The thickness of the ALD coating 32 may widely vary. In specific, but non-exclusive embodiments, the thickness may be 100, 150, or 200 nanometers. The above-listed thicknesses are merely exemplary and other thicknesses may be used. For instance, the ALD coating 32 may range anywhere from 20 to 500 nanometers in thickness. The desired thickness of the deposited ALD coating 32 for a given showerhead-electrode 14 may vary based on factors, such as longevity (e.g., the thicker the greater the longevity), the diameter of the holes defined by the gas conduits 26, the ALD processing time needed to deposit the ALD coating 32 to the desired thickness, etc.

The material of the ALD coating 32 deposited during the ALD process may also vary. Exemplary materials include, but by no means are limited to, aluminum oxide, yttrium, yttrium aluminum oxide, yttrium oxide, silicon, spinel, or other silicon-based coatings including silicon oxide (SiO₂), or any other material suitable for use within a plasma etching chamber. In the specification and claims, spinel is a crystal containing material comprising a magnesium aluminum oxynitride. The ALD coating 32 may, therefore, be the same or different than the materials (a) through (g) used to fabricate the showerhead-electrode 14.

In one specific, but by no means exclusive embodiment, the showerhead-electrode 14 and the ALD coating 32 are both silicon. The use of the same material includes the benefits of at least partially filling and sealing surface defects with the same material as the underlying material used to fabricate the showerhead-electrode 14. Also, like materials will have similar coefficients of thermal expansion and a similar signature as seen by the plasma 28 within the chamber 12.

### Inductively Coupled Plasma Tools

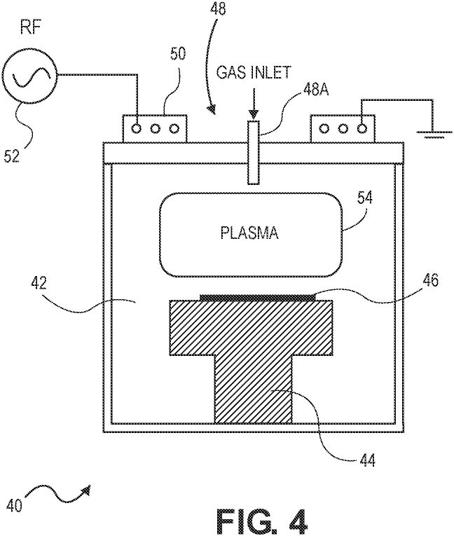

Referring to FIG. 4 a block diagram of an Inductively Coupled Plasma (ICP) etching tool 40 is illustrated. The ICP etching tool 40 includes a chamber 42, a pedestal 44 for supporting a workpiece 46 within the chamber 42, one or more gas nozzles 48 (for the sake of simplicity, only one gas nozzle is shown) for introducing gas or gases into the chamber 42, an induction coil 50 and RF power source 52. As is well known in the art, the RF power source 52 provides a time-varying current through the induction coil 50, generating plasma 54 from the resulting magnetic field. Since the plasma is generated inductively, the ICP etching tool 40 is often referred to as an ICP tool.

The one or more gas nozzles 48 each include a component body 48A that can be made from a wide variety of materials. In various embodiments, the gas nozzle(s) 48 may be fabricated from the same materials (a) through (g) as listed above or just about any other material suitable for operation within a plasma environment. The gas nozzle(s) 48 may also include one or more gas conduits (not illustrated), as described in detail below, that are used to supply one or more gases into the chamber 42. These gas conduits are similarly fabricated using various machining or drilling techniques, such as EDM, milling, CNC machining, etc. Regardless of how fabricated, the internal walls of the gas conduits tend to have surface defects, including cracking, waffling, material overhang, undercut, etc., and are thus susceptible to erosion and particle generation. Since the gas conduits are susceptible to erosion, an ALD coating at least partially sealing their internal walls is beneficial with this embodiment as well.

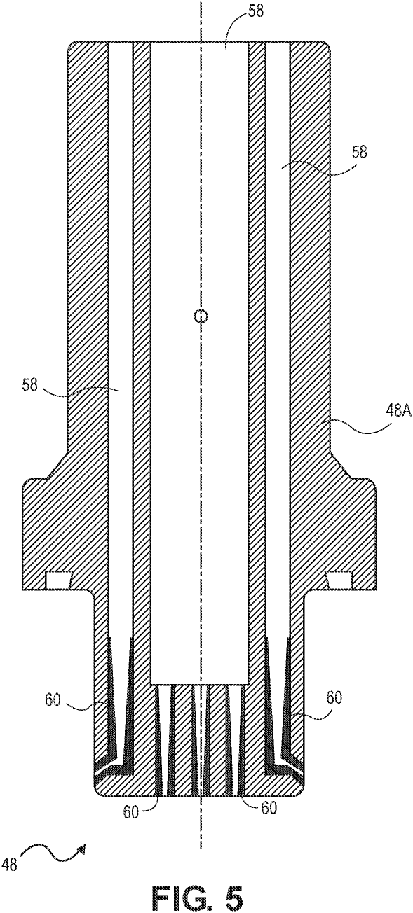

Referring to FIG. 5, a cross-section of the component body 48A of the gas nozzle 48 is shown. The component body 38A may be made from any of the above-listed materials (a) through (g) or other suitable materials and includes one or more gas conduits 58 that are fabricated or otherwise machined into the body 48A using any of the above-listed techniques, including EDM, milling, CNC machining, drilling, etc. As depicted, some of the gas conduits 58 are arranged to inject a gas directly into the chamber 42, while other gas conduits 58 are arranged to direct gas into the chamber at an angle.

To prevent or at least mitigate erosion and particle generation, an ALD coating 60 is deposited over at least portions of the inner walls of the gas nozzles 48. Similar to as previously described, the ALD coating 60 on the inner walls may be of non-uniform thickness, meaning thicker at the gas outlet and gradually tapering along the length of the gas conduits 58. In other embodiments, the ALD coating 60 may be of uniform thickness. In various embodiments, the thickness of the ALD coating 60 may widely vary from 20 to 500 nanometers. Again, by providing the ALD coating 60 at the gas outlet of the gas conduits 58, the surface areas most susceptible to erosion and particle generation are sealed. As a result, the generation of unwanted particles and other contaminants is significantly reduced or altogether eliminated.

The ALD coating 60 may be made of different materials. Exemplary materials include, but by no means are limited to, aluminum oxide, yttrium, yttrium aluminum oxide, yttrium oxide, silicon, or other silicon-based coatings including silicon oxide (SiO₂), or any other material suitable for use within a plasma etching chamber.

In the above-described embodiments, the use of an ALD coating for sealing surfaces of two different types of gas dispensing components is described. It should be understood, however, that the scope of the present disclosure as contemplated herein is by no means limited to just gas dispensing components. On the contrary, the present disclosure contemplates that such an ALD coating can be deposited on just about any type of component within an etching chamber. Such other components may include non-gas dispensing holes, such as used for housing a sensor of some kind, or simply any machined surface, whether flat, contoured, curved, non-uniform, or other shapes. In each case, an ALD coating may be used to eliminate or mitigate surface erosion and particle generation when exposed to plasma or other radicals within an etching chamber.

### Other Component Parts

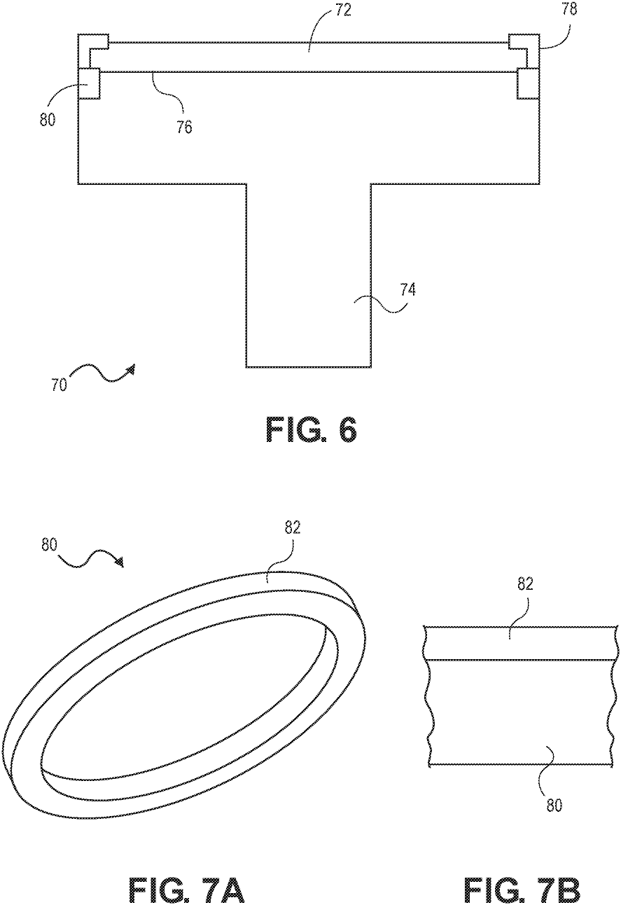

Referring FIG. 6, a cross-section of a pedestal 70 for supporting a workpiece 72 within an etching chamber (not shown) of either a CCP or ICP etching tool is shown. The pedestal 70 includes a body 74 and defines a clamping surface 76 for clamping the workpiece 72 in place. In various embodiments, the pedestal 70 may clamp the workpiece 72 to surface 76 in ways such as electro-statically as is the case with an ESC type chuck, mechanically, via a vacuum, or any combination thereof.

The pedestal 70 may also include one or more edge rings 78, 80 that surrounds the periphery of the workpiece 72. Such rings 78, 80 may perform different functions. For example, the upper ring 78 may aid in mechanically clamping or otherwise positioning the workpiece 72 in place. The ring 80 may be used as a power delivering electrode within the processing chamber.

In various embodiments, the rings 78, 80 are machined from any of the above-listed materials used to fabricate components, such as materials (a) through (g) as listed above or just about any other material suitable for operation within a plasma environment. Also, the rings 78, 80 can be fabricated using any of the above-listed approaches, such as EDM, milling, CNC machining, drilling, etc. Since such rings are typically machined, surface defects such as those described above are typically present.

Ring 80, since it is positioned below upper ring 78, is typically not in the direct line of sight of the plasma in the processing tool the pedestal 70 is used. The ring 80, nevertheless, may still be exposed to radicals during substrate processing. As a result, the machined surfaces of ring 80 may experience erosion, generating unwanted particles. As such, an ALD coating can similarly be advantageously used on ring 80 to prevent or mitigate unwanted particle generation.

Referring to FIGS. 7A and 7B, an ALD coating 82 is provided on ring 80. In alternative embodiments, the ALD coating 82 is provided on the entire external surface of the ring 80 or at least portions thereof. Similarly, the ALD coating 82 may be made from any of the above-listed materials, including, but by no means are limited to, aluminum oxide, yttrium, yttrium aluminum oxide, yttrium oxide, silicon or other silicon-based coatings including silicon oxide (SiO₂), or any other material suitable for use within a plasma etching chamber. The ALD coating 82 may also have a thickness ranging anywhere from 20 to 500 nanometers. By depositing the ALD coating 82, the machined surfaces of the ring 80 are effectively sealed, preventing or mitigating particle generation caused by erosion and surface breakdown.

Although not described in detail, the upper ring 78 can also be sealed with a similar ALD coating.

The rings 78, 80 are each components that are used in a plasma chamber, such as either the CCP or ICP tools as described herein. It should be noted that the specific components as described herein should not be construed as limiting in any regard. On the contrary, portions of the body of any component used in an etching chamber, regardless if in a direct line of sight or not of the plasma, may be sealed using an ALD coating as described herein. As a result, the generation of unwanted particle generation and other contaminants can be significantly reduced.

### Component Fabrication Process Flow

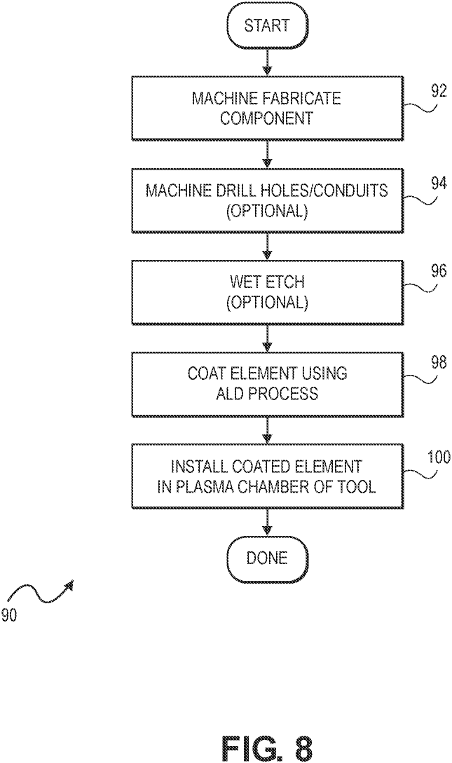

Referring to FIG. 8, a flow diagram 90 illustrating fabrication steps for ALD coating a body of a component part for use in either a CCP or ICP type etching tool is shown. The part that is fabricated can be any component used in a plasma etching chamber, including but not limited to the showerhead-electrode 14, a gas nozzle 48, either of rings 78, 80, or any other component within a plasma etch chamber. As many components used in such chambers are machined, the ALD coating process as described herein can be used to eliminate or reduce particle generation caused by erosion.

In the initial step 92, the body of the component part is fabricated. As previously noted, a given component part may be fabricated from different materials such as silicon, ceramic, non-oxide ceramic, oxide, ceramic, silicon carbide, aluminum oxide, aluminum, or just about any other material suitable for operation within a plasma environment. Also, different fabrication approaches may be used, including EDM, CNC machining, molding, milling, drilling, etc.

In an optional step 94, depending on the nature of the component part, the body of the component may be machined for multiple reasons. In the case of the showerhead-electrode 14 and the gas nozzle 48, gas conduits 26, 58 are drilled using EDM as described herein. With other types of component parts, holes, recesses or other features may be machined using EDM, milling drilling, etc. For example, a component part may have a hole or recess drilled to accommodate another component part, a sensor, for receiving fastening elements such as screws or bolts, etc. In yet other embodiments, the body of the component part, including any holes or recesses formed therein, may be fabricated using, additive manufacturing (e.g., 3D printing).

In optional step 96, surfaces of the component part may undergo a wet or chemical etching. As previously noted, wet etching tends to ameliorate surface defects reducing to some extent the degree of cracking, waffling, undercutting, and overcutting of the material.

In step 98, at least portions or all of the body of the component part is sealed with an ALD coating. This step involves placing the body of the component part into a processing chamber of an ALD tool and performing multiple ALD cycles until the ALD coating is the desired thickness. The ALD coating may be made from any of the above-listed materials, including, but by no means are limited to, aluminum oxide, yttrium, yttrium aluminum oxide, yttrium oxide, silicon or other silicon-based coatings including silicon oxide (SiO₂), or any other material suitable for use within a plasma etching chamber.

Finally, in step 100, the coated component is installed into a plasma etching tool.

### ALD Process Flow

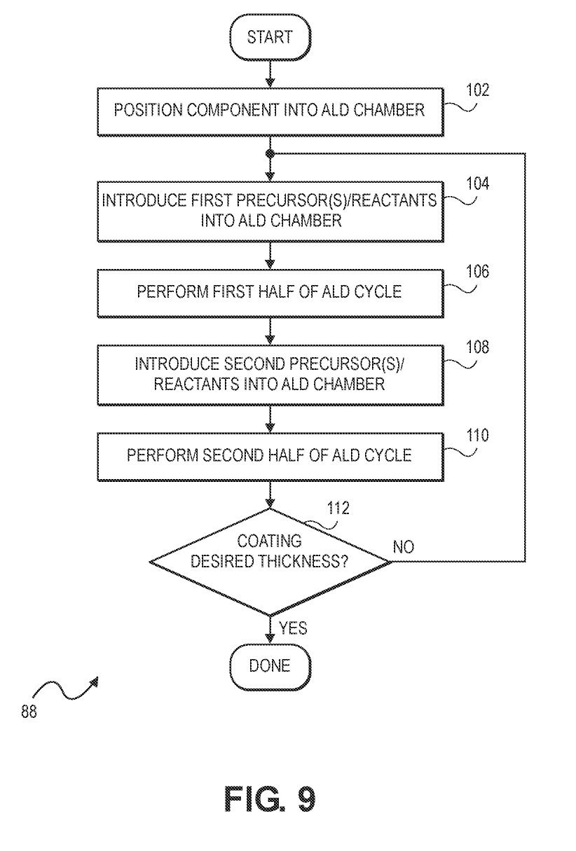

Referring to FIG. 9 a flow diagram of an ALD process implemented in step 88 of FIG. 8 as described above is illustrated.

In the initial step 102, the component part is positioned in the processing chamber of an ALD tool.

In steps 104 and 106, the first half of an ALD cycle is performed. The first half cycle involves introducing first precursor(s) and/or reactants into the processing chamber, generating plasma, and depositing a first layer of particles onto the surfaces of the component. Thereafter, the processing chamber is then purged.

In steps 108 and 110, the second half of the ALD cycle is performed. These steps involve introducing a second precursor and/or reactant into the processing chamber, generating the plasma, and depositing a second layer of particles onto the surfaces of the component. Thereafter, the processing chamber is purged.

The first and second half ALD steps as described herein rely on a plasma. It should be noted, however, that this is by no means a requirement. In other embodiments, either the first and/or the second half ALD steps can be plasma-less. In addition, any other deposition process may be used, such as for example, Chemical Vapor Deposition (CVD), Physical Vapor Deposition, or any other processes capable of depositing thin films.

In the decision step 112, it is determined if the ALD coating resulting from the deposition of the first and second layer of particles has reached the desired thickness. If not, then steps 104 through 110 are repeated. If yes, then the above process is complete.

As previously noted, the ALD coating may be made from a wide variety of different materials, including but not limited to aluminum oxide, yttrium, yttrium aluminum oxide, yttrium oxide, silicon or other silicon-based coatings including silicon oxide (SiO₂), or any other material suitable for preventing or mitigating erosion within a plasma etching chamber may be used. Different precursors and/or reactants are typically used for each of the different material choices. When depositing an ALD layer of silicon or aluminum oxide, for example, precursors containing silicon (e.g., SiO₂) or aluminum (e.g., trimethylaluminum (TMA) Al(CH₃)₃) and a reactant such as water (H₂O) are used. For the remainder of the ALD materials, suitable precursors and/or reactants can be used.

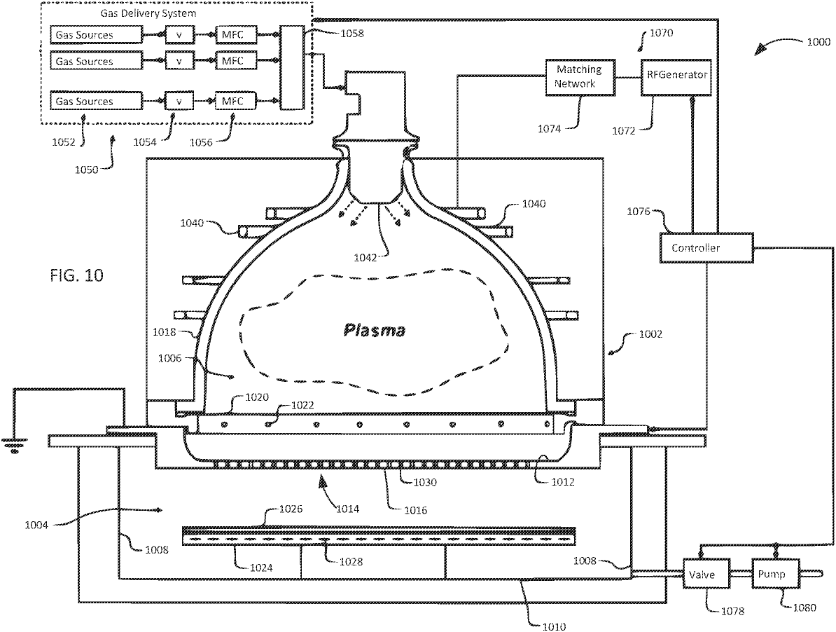

FIG. 10 is a schematic cross sectional view of another semiconductor processing system 1000. The semiconductor processing system includes a processing chamber (i.e., a substrate processing chamber) 1002. Although the processing chamber 1002 is shown as an inductively coupled plasma (ICP) based system, the examples disclosed herein may be applied to other types of substrate processing systems such as transformer coupled plasma (TCP) or downstream plasma systems.

The processing chamber 1002 includes a lower chamber region 1004 and an upper chamber region 1006. The lower chamber region 1004 is defined by chamber sidewall surfaces 1008, a chamber bottom surface 1010, and a lower surface of a gas or plasma distribution device such as a showerhead assembly including a showerhead 1014. For example, the showerhead 1014 may include a faceplate 1016 configured to function as an ion and/or ultraviolet (UV) filter/blocker. Radicals energized within the interior volume of the upper chamber region 1006 bounce/reflect off of surfaces of the upper chamber region 1006 and faceplate 1016, through holes 1030 and into lower chamber region 1004 of the processing chamber 1000 to form the etching process on the substrate 1026.

In some examples, the faceplate 1016 is connected to a reference potential such as ground (as shown in FIG. 10). In other examples, the faceplate 1016 may be connected to a positive or negative direct current (DC) reference potential.

The upper chamber region 1006 is defined by an upper surface 1012 of the showerhead 1014 and an inner surface of a dome 1018. In some examples, the dome 1018 rests on a first annular support 1020 including one or more spaced holes 1022 for optionally delivering process gas or gasses (e.g. helium, hydrogen, or the like) to the upper chamber region 1006. In some examples, the process gas is delivered by the one or more spaced holes 1022 in an upward direction at an acute angle relative to a plane including the showerhead 1014, although other angles/directions may be used. A gas flow channel (not shown) in the first annular support 1020 may be used to supply gas to the one or more spaced holes 1022.

A depth of the showerhead 1014 (i.e., an amount that the faceplate 1016 extends into the interior volume of lower chamber 1004) defines a gap between a lower surface of the faceplate 1016 and the substrate 1026. The gap (i.e., a gap width or distance) is optimized to achieve a desired etch profile. For example, etch uniformity may vary across different processes, processing chambers, etc. Accordingly, the showerhead 1014 is configured to achieve a desired gap for a particular process and/or processing chamber. For example, the gap may be varied between 1 and 10 inches (e.g., 25 to 76 mm). In one embodiment, the showerhead 1014 may be removed and replaced to adjust the gap.

The substrate or wafer support 1024 is arranged in the lower chamber region 1004. In some examples, the substrate support 1024 includes an electrostatic chuck (ESC), although other types of substrate supports can be used. A substrate or wafer 1026 is arranged on an upper surface of the substrate support 1024 during processing such as etching. In some examples, a temperature of the substrate 1026 may be controlled by heating elements (or a heater plate) 128, an optional cooling plate with fluid channels and one or more sensors (not shown), and/or any other suitable substrate support temperature control systems.

One or more inductive coils 1040 may be arranged around an outer portion of the dome 1018. When energized, the one or more inductive coils 1040 create an electromagnetic field inside of the dome 1018. In some examples, an upper coil and lower coil are used. A gas injector 1042 injects one or more gas mixtures from a gas delivery system 1050. The gas delivery system 1050 includes one or more gas sources 1052, one or more valves 1054, one or more mass flow controllers (MFCs) 1056, and a mixing manifold 1058, although other types of gas delivery systems may be used.

In some examples, the gas injector 1042 includes a center injection location that directs gas in a downward direction and one or more side injection locations that inject gas at one or more angles with respect to the downward direction. In some examples, the gas delivery system 1050 delivers a first portion of the gas mixture at a first flow rate to the center injection location and a second portion of the gas mixture at a second flow rate to the side injection locations of the gas injector 1042. In other examples, differing mixtures are delivered by the gas injector 1042. In some examples, the gas delivery system 1050 delivers tuning gas to other locations in the processing chamber.

A plasma generator 1070 may be used to generate RF power that is output to the one or more inductive coils 1040. Plasma is generated in the upper chamber region. In some examples, the plasma generator 1070 includes an RF generator 1072 and a matching network 1074. The matching network 1074 matches an impedance of the RF generator 1072 to the impedance of the one or more inductive coils 1040. Although a single RF source (i.e., RF generator 1072) is shown, in other examples multiple RF sources may be used to supply two or more different pulsing levels. A valve 1078 and a pump 1080 may be used to control pressure inside of the lower and upper chamber regions 1004, 1006 and to evacuate reactants.

A controller 1076 communicates with the gas delivery system 1050, the valve 1078, the pump 1080, and/or the plasma generator 1070 to control flow of process gas, purge gas, RF plasma and chamber pressure. In some examples, plasma is sustained inside dome 1018 by the one or more inductive coils 1040. One or more gas mixtures are introduced from a top portion of the processing chamber 1002 using the gas injector 1042 (and/or holes 1022).

The showerhead 1014 according to the present disclosure includes one or more features configured to tune a desired etch profile of etching performed on the substrate 1026. For example, the showerhead 1014 may include an embedded heater (not shown in FIG. 10). The controller 1076 is configured to control the heater to control a temperature of the showerhead 1014 and maintain the desired etch profile. The faceplate 1016 includes holes 1030 arranged to flow plasma from the upper chamber region 1006, through the faceplate 1016, and into the lower chamber region 1004. An arrangement of the holes 1030 (e.g., hole diameter, pitch, pattern, etc.) according to the present disclosure may be optimized to achieve a desired etch profile. For example, the holes 1030 may be omitted/blocked in specific regions of the faceplate 1016. The showerhead 1014 according to the present disclosure may also protrude/extend into the lower chamber region 1004 (i.e., into an interior volume of the processing chamber 1002).

In an embodiment, the showerhead 1014 may have a component body of aluminum with an ALD coating within the holes 1030 of yttrium oxide. In such an embodiment, a remote plasma showerhead 1014 is the component with the protective ALD coating. In the same or another embodiment, passages in the gas injector 1042 may have a protective ALD coating.

It should be understood that the embodiments provided herein are merely exemplary and should not be construed as limiting in any regard. In general, the present application is intended to cover any a showerhead having at least two sets of holes defining two spiral patterns and two plenums for the two patterns respectfully.

Although only a few embodiments have been described in detail, it should be appreciated that the present application may be implemented in many other forms without departing from the spirit or scope of the disclosure provided herein.

Therefore, the present embodiments should be considered illustrative and not restrictive and should not to be limited to the details given herein, but may be modified within the scope and equivalents of the appended claims.

What is claimed is:

1. A component, the component including:
a component body with one or more holes formed therein; and
an Atomic Layer Deposition (ALD) coating deposited on at least a portion of an internal surface of the one or more holes respectively.

2. The component of claim 1, wherein the component body is fabricated from one of the following:
(a) silicon;
(b) non-oxide ceramic;
(c) oxide ceramic;
(d) silicon carbide;
(e) aluminum;
(f) aluminum oxide (Al₂O₃); or
(g) yttrium oxide (Y₂O₃).

3. The component of claim 1, wherein the ALD coating is selected from a group including:
(a) aluminum oxide;
(b) yttrium aluminum oxide
(c) yttrium oxide;
(d) silicon;
(e) silicon oxide; or
(f) spinel.

4. The component of claim 1, wherein the ALD coating eliminates or mitigates particle generation caused by erosion when the component is exposed to plasma.

5. The component of claim 1, wherein the component body is fabricated from silicon and the ALD coating is also silicon.

6. The component of claim 1, wherein the ALD coating has a thickness in a range of 20 to 500 nanometers.

7. The component of claim 1, wherein the component is a gas dispensing component for use in a plasma chamber and the one or more holes formed in the component body are one or more gas conduits.

8. The component of claim 7, wherein the ALD coating is either:
(a) thicker at a gas outlet of the one or more gas conduits and gradually tapers along a length of the one or more gas conduits respectively; or
(b) uniform in thickness along the length of the one or more gas conduits respectfully.

9. The component of claim 1, wherein the one or more holes are formed in the component by one of the following:
(a) Electrical Discharge Machining (EDM);
(b) additive manufacturing;
(c) milling;
(d) drilling;
(e) computer numerical control (CNC) machining; or
(f) any combination of (a) through (e).

10. The component of claim 7, wherein the one or more gas conduits have a diameter of one or more of the following:
(a) approximately 500 microns;
(b) in a range of 400 to 600 microns;
(c) less than 600 microns; or
(d) more than 400 microns.

11. The component of claim 7, wherein the one or more gas conduits have an aspect ratio of one or more of the following:
(a) approximately 30:1;
(b) in a range of 20:1 to 40:1;
(c) more than 20:1; or
(d) less than 40:1.

12. The component of claim 7, wherein the gas dispensing component is a showerhead.

13. The component of claim 12, wherein the showerhead also acts as an electrode providing Radio Frequency (RF) energy within the plasma chamber and the plasma chamber is provided in a Capacitively Couple Plasma (CCP) etching tool.

14. The component of claim 7, wherein the gas dispensing component is a gas dispensing nozzle and the plasma chamber is provided on an Inductively Coupled Plasma (ICP) etching tool.

15. The component of claim 7, wherein the one or more gas conduits each define internal walls that are wet etched before depositing the ALD coating.

16. A component for use in a plasma etching chamber, the component comprising:
a component body made of silicon; and
an Atomic Layer Deposition (ALD) silicon coating deposited on at least a portion of the component body, the ALD silicon coating eliminating or mitigating erosion of at least the portion of the component body covered by the ALD silicon coating when exposed to an environment within the plasma etching chamber.

17. The component of claim 16, wherein the ALD silicon coating ranges in thickness from 20 to 500 nanometers.

18. The component of claim 16, wherein the component body is a silicon ring and the ALD silicon coating is provided to eliminate or mitigate particle generation when the silicon ring is exposed to radicals in the plasma etching chamber.

19. The component of claim 16, wherein the component body is a silicon ring that is intended to (a) surround an edge periphery of a semiconductor wafer when positioned on a support surface within the plasma etching chamber and (b) operate as a power delivering electrode within the plasma etching chamber.

20. The component of claim 16, wherein the component body is a showerhead and the ALD silicon coating is deposited within gas outlets of gas conduits formed in the showerhead.

21. The component of claim 16, wherein the component body is a gas nozzle for supplying gas into an etching chamber of an Inductively Coupled Plasma etching tool and the ALD silicon coating is deposited within one or more gas outlets of one or more gas conduits fabricated in the gas nozzle.

22. A method for fabricating a component for use in a plasma etching chamber, the method comprising:
fabricating a component body of the component from a material with one or more holes formed in the material of the component body;
wet etching internal surfaces of the one or more holes formed in the material of the component body; and
depositing an Atomic Layer Deposition (ALD) coating using an ALD process at least partially onto internal surfaces of the one or more holes formed in the material of the component body, the ALD coating acting to seal surface defects on the internal surfaces resulting from the formation therein.

23. The method of claim 22, wherein depositing the ALD coating further comprises using the ALD process until the ALD coating has a thickness in a range of 20 to 500 nanometers.

24. The method of claim 22, wherein the component is a showerhead.

25. The method of claim 22, wherein the component is a gas nozzle for supplying gas into an etching chamber of an Inductively Coupled Plasma (ICP) etching tool.

26. The method of claim 22, wherein the material the component body is fabricated from is selected from one of the following:
(a) silicon;
(b) non-oxide ceramic;
(c) oxide ceramic;
(d) silicon carbide;
(e) aluminum;
(f) aluminum oxide (Al₂O₃); or
(g) yttrium oxide (Y₂O₃).

27. The method of claim 22, wherein the material the component body and the ALD coating are both silicon.

28. The method of claim 22, wherein the ALD coating comprises:
(a) aluminum oxide;
(b) yttrium aluminum oxide
(c) yttrium oxide;
(d) silicon;
(e) silicon oxide; and
(f) spinel.

29. The method of claim 22, wherein fabricating the component body of the component with the one or more holes formed in the material further comprises using one of the following fabrication processes:
(a) Electrical Discharge Machining (EDM);
(b) additive manufacturing;
(c) milling;
(d) drilling;
(e) computer numerical control (CNC) machining; or
(f) any combination of (a) through (e).

30. A component for use in a plasma etching chamber, the component made using the method of claim 22.

31. The component of claim 30, wherein the component is a showerhead.

32. The component of claim 30, wherein the component is a gas nozzle for use in an etching chamber of an Inductively Coupled Plasma (ICP) etching tool.
